(19) United States
(12) Patent Application Publication
(10) Pub. No.: US 2005/0191786 A1
(43) Pub. Date: Sep. 1, 2005

(54) Integrated circuit packaging using electrochemically fabricated structures

(75) Inventors: Adam L. Cohen, Los Angeles, CA (US); Vacit Arat, La Canada Flintridge, CA (US); Michael S. Lockard, Lake Elizabeth, CA (US)

Correspondence Address: MICROFABRICA INC.;DENNIS R. SMALLEY, 1103 W. ISABEL ST., BURBANK, CA, 91506, US

(73) Assignee: Microfabrica Inc.

(21) Appl. No.: 11/029,185

(22) Filed: Jan. 3, 2005

Related U.S. Application Data
(60) Provisional application No. 60/533,948, filed on Dec. 31, 2003.
(60) Provisional application No. 60/574,737, filed on May 26, 2004.
(60) Provisional application No. 60/603,030, filed on Aug. 19, 2004.
(60) Provisional application No. 60/610,083, filed on Sep. 14, 2004.

(51) Int. Cl. H01L 21/44; H01L 21/50

(52) U.S. Cl. 438/106; 438/119

(57) ABSTRACT

Embodiments of the invention provide a package for holding an integrated circuit or other electronic component and/or a packaged integrated circuit or electronic component which is formed at least in part via an electrochemical fabrication process from a plurality of adhered layers of conductive and dielectric materials.

### RELATED APPLICATIONS

This application claims benefit of U.S. Provisional Patent Applications 60/533,948, filed Dec. 31, 2003; 60/574,737, filed May 26, 2004; 60/603,030, filed Aug. 19, 2004, and 60/610,083, filed Sep. 14, 2004. Each of these applications is incorporated herein by reference.

### FIELD OF THE INVENTION

The present invention relates generally to the field of electrochemical fabrication and the associated formation of three-dimensional structures (e.g. microscale or mesoscale structures). In particular, it relates to electrochemical fabrication methods for fabricating packages for integrated circuits where at least a portion of the package is formed using electrochemical fabrication techniques.

### BACKGROUND OF THE INVENTION

A technique for forming three-dimensional structures (e.g. parts, components, devices, and the like) from a plurality of adhered layers was invented by Adam L. Cohen and is known as Electrochemical Fabrication. It is being commercially pursued by Microfabrica Inc. (formerly MEMGen®) Corporation) of Burbank, Calif. under the name EFAB™. This technique was described in U.S. Pat. No. 6,027,630, issued on Feb. 22, 2000. This electrochemical deposition technique allows the selective deposition of a material using a unique masking technique that involves the use of a mask that includes patterned conformable material on a support structure that is independent of the substrate onto which plating will occur. When desiring to perform an electrodeposition using the mask, the conformable portion of the mask is brought into contact with a substrate while in the presence of a plating solution such that the contact of the conformable portion of the mask to the substrate inhibits deposition at selected locations. For convenience, these masks might be generically called conformable contact masks; the masking technique may be generically called a conformable contact mask plating process. More specifically, in the terminology of Microfabrica Inc. (formerly MEMGen® Corporation) of Burbank, Calif. such masks have come to be known as INSTANT MASKS™ and the process known as INSTANT MASKING™ or INSTANT MASK™ plating. Selective depositions using conformable contact mask plating may be used to form single layers of material or may be used to form multi-layer structures. The teachings of the '630 patent are hereby incorporated herein by reference as if set forth in full herein. Since the filing of the patent application that led to the above noted patent, various papers about conformable contact mask plating (i.e. INSTANT MASKING) and electrochemical fabrication have been published:

1. A. Cohen, G. Zhang, F. Tseng, F. Mansfeld, U. Frodis and P. Will, “EFAB: Batch production of functional, fully-dense metal parts with micro-scale features”, Proc. 9th Solid Freeform Fabrication, The University of Texas at Austin, p161, August 1998.

(2) A. Cohen, G. Zhang, F. Tseng, F. Mansfeld, U. Frodis and P. Will, “EFAB: Rapid, Low-Cost Desktop Micromachining of High Aspect Ratio True 3-D MEMS”, Proc. 12th IEEE Micro Electro Mechanical Systems Workshop, IEEE, p244, January 1999.

(3) A. Cohen, “3-D Micromachining by Electrochemical Fabrication”, Micromachine Devices, March 1999.

(4) G. Zhang, A. Cohen, U. Frodis, F. Tseng, F. Mansfeld, and P. Will, “EFAB: Rapid Desktop Manufacturing of True 3-D Microstructures”, Proc. 2nd International Conference on Integrated MicroNanotechnology for Space Applications, The Aerospace Co., April 1999.

(5) F. Tseng, U. Frodis, G. Zhang, A. Cohen, F. Mansfeld, and P. Will, “EFAB: High Aspect Ratio, Arbitrary 3-D Metal Microstructures using a Low-Cost Automated Batch Process”, 3rd International Workshop on High Aspect Ratio MicroStructure Technology (HARMST'99), June 1999.

(6) A. Cohen, U. Frodis, F. Tseng, G. Zhang, F. Mansfeld, and P. Will, “EFAB: Low-Cost, Automated Electrochemical Batch Fabrication of Arbitrary 3-D Microstructures”, Micromachining and Microfabrication Process Technology, SPIE 1999 Symposium on Micromachining and Microfabrication, September 1999.

(7) F. Tseng, G. Zhang, U. Frodis, A. Cohen, F. Mansfeld, and P. Will, “EFAB: High Aspect Ratio, Arbitrary 3-D Metal Microstructures using a Low-Cost Automated Batch Process”, MEMS Symposium, ASME 1999 International Mechanical Engineering Congress and Exposition, November, 1999.

(8) A. Cohen, “Electrochemical Fabrication (EFAB™)”, Chapter 19 of The MEMS Handbook, edited by Mohamed Gad-El-Hak, CRC Press, 2002.

(9) Microfabrication-Rapid Prototyping's Killer Application”, pages 1-5 of the Rapid Prototyping Report, CAD/CAM Publishing, Inc., June 1999.

The disclosures of these nine publications are hereby incorporated herein by reference as if set forth in full herein.

The electrochemical deposition process may be carried out in a number of different ways as set forth in the above patent and publications. In one form, this process involves the execution of three separate operations during the formation of each layer of the structure that is to be formed:
(1) Selectively depositing at least one material by electrodeposition upon one or more desired regions of a substrate.
(2) Then, blanket depositing at least one additional material by electrodeposition so that the additional deposit covers both the regions that were previously selectively deposited onto, and the regions of the substrate that did not receive any previously applied selective depositions.
(3) Finally, planarizing the materials deposited during the first and second operations to produce a smoothed surface of a first layer of desired thickness having at least one region containing the at least one material and at least one region containing at least the one additional material.

After formation of the first layer, one or more additional layers may be formed adjacent to the immediately preceding layer and adhered to the smoothed surface of that preceding layer. These additional layers are formed by repeating the first through third operations one or more times wherein the formation of each subsequent layer treats the previously formed layers and the initial substrate as a new and thickening substrate.

Once the formation of all layers has been completed, at least a portion of at least one of the materials deposited is generally removed by an etching process to expose or release the three-dimensional structure that was intended to be formed.

The preferred method of performing the selective electrodeposition involved in the first operation is by conformable contact mask plating. In this type of plating, one or more conformable contact (CC) masks are first formed. The CC masks include a support structure onto which a patterned conformable dielectric material is adhered or formed. The conformable material for each mask is shaped in accordance with a particular cross-section of material to be plated. At least one CC mask is needed for each unique cross-sectional pattern that is to be plated.

The support for a CC mask is typically a plate-like structure formed of a metal that is to be selectively electroplated and from which material to be plated will be dissolved. In this typical approach, the support will act as an anode in an electroplating process. In an alternative approach, the support may instead be a porous or otherwise perforated material through which deposition material will pass during an electroplating operation on its way from a distal anode to a deposition surface. In either approach, it is possible for CC masks to share a common support, i.e. the patterns of conformable dielectric material for plating multiple layers of material may be located in different areas of a single support structure. When a single support structure contains multiple plating patterns, the entire structure is referred to as the CC mask while the individual plating masks may be referred to as “submasks”. In the present application such a distinction will be made only when relevant to a specific point being made.

In preparation for performing the selective deposition of the first operation, the conformable portion of the CC mask is placed in registration with and pressed against a selected portion of the substrate (or onto a previously formed layer or onto a previously deposited portion of a layer) on which deposition is to occur. The pressing together of the CC mask and substrate occur in such a way that all openings, in the conformable portions of the CC mask contain plating solution. The conformable material of the CC mask that contacts the substrate acts as a barrier to electrodeposition while the openings in the CC mask that are filled with electroplating solution act as pathways for transferring material from an anode (e.g. the CC mask support) to the non-contacted portions of the substrate (which act as a cathode during the plating operation) when an appropriate potential and/or current are supplied.

An example of a CC mask and CC mask plating are shown in FIGS. 1A-1C. FIG. 1A shows a side view of a CC mask 8 consisting of a conformable or deformable (e.g. elastomeric) insulator 10 patterned on an anode 12. The anode has two functions. FIG. 1A also depicts a substrate 6 separated from mask 8. One is as a supporting material for the patterned insulator 10 to maintain its integrity and alignment since the pattern may be topologically complex (e.g., involving isolated “islands” of insulator material). The other function is as an anode for the electroplating operation. CC mask plating selectively deposits material 22 onto a substrate 6 by simply pressing the insulator against the substrate then electrodepositing material through apertures 26a and 26b in the insulator as shown in FIG. 1B. After deposition, the CC mask is separated, preferably non-destructively, from the substrate 6 as shown in FIG. 1C. The CC mask plating process is distinct from a “through-mask” plating process in that in a through-mask plating process the separation of the masking material from the substrate would occur destructively. As with through-mask plating, CC mask plating deposits material selectively and simultaneously over the entire layer. The plated region may consist of one or more isolated plating regions where these isolated plating regions may belong to a single structure that is being formed or may belong to multiple structures that are being formed simultaneously. In CC mask plating as individual masks are not intentionally destroyed in the removal process, they may be usable in multiple plating operations.

Another example of a CC mask and CC mask plating is shown in FIGS. 1D-1F. FIG. 1D shows an anode 12′ separated from a mask 8′ that includes a patterned conformable material 10′ and a support structure 20. FIG. 1D also depicts substrate 6 separated from the mask 8′. FIG. 1E illustrates the mask 8′ being brought into contact with the substrate 6. FIG. 1F illustrates the deposit 22′ that results from conducting a current from the anode 12′ to the substrate 6. FIG. 1G illustrates the deposit 22′ on substrate 6 after separation from mask 8′. In this example, an appropriate electrolyte is located between the substrate 6 and the anode 12′ and a current of ions coming from one or both of the solution and the anode are conducted through the opening in the mask to the substrate where material is deposited. This type of mask may be referred to as an anodeless INSTANT MASK™ (AIM) or as an anodeless conformable contact (ACC) mask.

Unlike through-mask plating, CC mask plating allows CC masks to be formed completely separate from the fabrication of the substrate on which plating is to occur (e.g. separate from a three-dimensional (3D) structure that is being formed). CC masks may be formed in a variety of ways, for example, a photolithographic process may be used. All masks can be generated simultaneously, prior to structure fabrication rather than during it. This separation makes possible a simple, low-cost, automated, self-contained, and internally-clean “desktop factory” that can be installed almost anywhere to fabricate 3D structures, leaving any required clean room processes, such as photolithography to be performed by service bureaus or the like.

An example of the electrochemical fabrication process discussed above is illustrated in FIGS. 2A-2F. These figures show that the process involves deposition of a first material 2 which is a sacrificial material and a second material 4 which is a structural material. The CC mask 8, in this example, includes a patterned conformable material (e.g. an elastomeric dielectric material) 10 and a support 12 which is made from deposition material 2. The conformal portion of the CC mask is pressed against substrate 6 with a plating solution 14 located within the openings 16 in the conformable material 10. An electric current, from power supply 18, is then passed through the plating solution 14 via (a) support 12 which doubles as an anode and (b) substrate 6 which doubles as a cathode. FIG. 2A, illustrates that the passing of current causes material 2 within the plating solution and material 2 from the anode 12 to be selectively transferred to and plated on the cathode 6. After electroplating the first deposition material 2 onto the substrate 6 using CC mask 8, the CC mask 8 is removed as shown in FIG. 2B. FIG. 2C depicts the second deposition material 4 as having been blanket-deposited (i.e. non-selectively deposited) over the previously deposited first deposition material 2 as well as over the other portions of the substrate 6. The blanket deposition occurs by electroplating from an anode (not shown), composed of the second material, through an appropriate plating solution (not shown), and to the cathode/substrate 6. The entire two-material layer is then planarized to achieve precise thickness and flatness as shown in FIG. 2D. After repetition of this process for all layers, the multi-layer structure 20 formed of the second material 4 (i.e. structural material) is embedded in first material 2 (i.e. sacrificial material) as shown in FIG. 2E. The embedded structure is etched to yield the desired device, i.e. structure 20, as shown in FIG. 2F.

Various components of an exemplary manual electrochemical fabrication system 32 are shown in FIGS. 3A-3C. The system 32 consists of several subsystems 34, 36, 38, and 40. The substrate holding subsystem 34 is depicted in the upper portions of each of FIGS. 3A to 3C and includes several components: (1) a carrier 48, (2) a metal substrate 6 onto which the layers are deposited, and (3) a linear slide 42 capable of moving the substrate 6 up and down relative to the carrier 48 in response to drive force from actuator 44. Subsystem 34 also includes an indicator 46 for measuring differences in vertical position of the substrate which may be used in setting or determining layer thicknesses and/or deposition thicknesses. The subsystem 34 further includes feet 68 for carrier 48 which can be precisely mounted on subsystem 36.

The CC mask subsystem 36 shown in the lower portion of FIG. 3A includes several components: (1) a CC mask 8 that is actually made up of a number of CC masks (i.e. submasks) that share a common support/anode 12, (2) precision X-stage 54, (3) precision Y-stage 56, (4) frame 72 on which the feet 68 of subsystem 34 can mount, and (5) a tank 58 for containing the electrolyte 16. Subsystems 34 and 36 also include appropriate electrical connections (not shown) for connecting to an appropriate power source for driving the CC masking process.

The blanket deposition subsystem 38 is shown in the lower portion of FIG. 3B and includes several components: (1) an anode 62, (2) an electrolyte tank 64 for holding plating solution 66, and (3) frame 74 on which the feet 68 of subsystem 34 may sit. Subsystem 38 also includes appropriate electrical connections (not shown) for connecting the anode to an appropriate power supply for driving the blanket deposition process.

The planarization subsystem 40 is shown in the lower portion of FIG. 3C and includes a lapping plate 52 and associated motion and control systems (not shown) for planarizing the depositions.

Another method for forming microstructures from electroplated metals (i.e. using electrochemical fabrication techniques) is taught in U.S. Pat. No. 5,190,637 to Henry Guckel, entitled “Formation of Microstructures by Multiple Level Deep X-ray Lithography with Sacrificial Metal layers”. This patent teaches the formation of metal structure utilizing mask exposures. A first layer of a primary metal is electroplated onto an exposed plating base to fill a void in a photoresist, the photoresist is then removed and a secondary metal is electroplated over the first layer and over the plating base. The exposed surface of the secondary metal is then machined down to a height which exposes the first metal to produce a flat uniform surface extending across the both the primary and secondary metals. Formation of a second layer may then begin by applying a photoresist layer over the first layer and then repeating the process used to produce the first layer. The process is then repeated until the entire structure is formed and the secondary metal is removed by etching. The photoresist is formed over the plating base or previous layer by casting and the voids in the photoresist are formed by exposure of the photoresist through a patterned mask via X-rays or UV radiation.

Even though electrochemical fabrication as taught and practiced to date, has greatly enhanced the capabilities of microfabrication, and in particular added greatly to the number of metal layers that can be incorporated into a structure and to the speed and simplicity in which such structures can be made, room for enhancing the state of electrochemical fabrication exists as well as for adding to the types of devices that can be formed or co-fabricated with other devices.

### SUMMARY OF THE INVENTION

Objects and advantages of various aspects of the invention will be apparent to those of skill in the art upon review of the teachings herein. The various aspects of the invention, set forth explicitly herein or otherwise ascertained from the teachings herein, may address one or more of the above objects alone or in combination, or alternatively may address some other object of the invention ascertained from the teachings herein. It is not necessarily intended that all objects be addressed by any single aspect of the invention even though that may be the case with regard to some aspects.

In a first aspect of the invention a fabrication process for fabricating a package for holding an electronic component includes: (a) forming and adhering a layer of material to a previously formed layer and/or to a substrate, wherein the layer comprises a desired pattern of at least one material; and (b) repeating the forming and adhering operation of (a) a plurality of times to build up a configuration of conductive interconnect elements in a configuration of a desired package, wherein the plurality of layers are adhered to one another and comprise at least one of (i) at least one structural material and at least one sacrificial material or (ii) at least two structural materials one of which is a conductor and one of which is a dielectric.

In a specific variation of the first aspect, the package includes et al electrodeposited or electroless deposited on a layer by layer basis where the height of at least some layers is set by a planarization operation that planarizes an interconnect material and at least one other material.

In a specific variation of the first aspect, the package includes vias and traces that coexist on at least some layers.

In a specific variation of the first aspect, the package includes at least one more coaxial interconnects.

In a specific variation of the first aspect, the package includes interconnects having traces having at least two different widths.

In a specific variation of the first aspect, the package includes interconnects comprising vias that have at least two different widths.

In a specific variation of the first aspect, the package includes interconnects have trace thicknesses that are at least as thick as some planarized thicknesses of a dielectric material.

In a specific variation of the first aspect, the package includes interconnects having trace thicknesses that are at least as thick as the differential height between some interconnect traces.

In a specific variation of the first aspect, at least one layer of the package is formed using a process comprising: patterning a first material, applying a non-planar seed layer, electrodepositing a second material, and trimming off at least a portion of the deposited first material.

In a second aspect of the invention, a fabrication process for fabricating a packaged electronic component includes: providing a substrate having conductive vias; forming routing elements on the substrate which have first and second ends, where at least some of the first ends are connectable to a first electronic component and at least some of the second ends connect to vias on the substrate; and attaching the first electronic component to at least some of the first ends.

In a third aspect of the invention, a fabrication process for fabricating a packaged electronic component, includes: providing a substrate; forming routing elements on the substrate which have first and second ends, where at least some of the first ends are connectable to a first electronic component and at least some of the second ends are connectable to a second electronic component; and attaching the first and second electronic components to the at least some of the first ends and second ends, respectively.

Further aspects of the invention will be understood by those of skill in the art upon reviewing the teachings herein. Other aspects of the invention may involve combinations of the above noted aspects of the invention. Other aspects of the invention may involve apparatus that can be used in implementing one or more of the above method aspects of the invention. These other aspects of the invention may provide various combinations of the aspects presented above as well as provide other configurations, structures, functional relationships, and processes that have not been specifically set forth above.

### BRIEF DESCRIPTION OF THE DRAWINGS

FIGS. 1A-1C schematically depict side views of various stages of a CC mask plating process, while FIGS. 1D-G schematically depict a side views of various stages of a CC mask plating process using a different type of CC mask.

FIGS. 2A-2F schematically depict side views of various stages of an electrochemical fabrication process as applied to the formation of a particular structure where a sacrificial material is selectively deposited while a structural material is blanket deposited.

FIGS. 3A-3C schematically depict side views of various example subassemblies that may be used in manually implementing the electrochemical fabrication method depicted in FIGS. 2A-2F.

FIGS. 4A-4I schematically depict the formation of a first layer of a structure using adhered mask plating where the blanket deposition of a second material overlays both the openings between deposition locations of a first material and the first material itself.

FIGS. 5A-5D schematically depict side views of various stages in a process for attaching an example IC to an example package where interconnects from the IC to at least one other component include vias that extend through a substrate on which electrochemically fabricated routing elements are formed.

FIG. 6 schematically depicts a side view of two example ICs attached to and at least partially electrically interconnected to one another via an example package and where at least a portion of the interconnects extend through routing elements formed via electrochemical fabrication.

FIG. 7 schematically depicts a side view of an example IC attached to an alternative example package configuration, where the package configuration includes a conductive substrate, routing elements that provide interconnect paths from a surface of the package to the IC, and which includes passive components such as inductors and capacitors.

FIG. 8 schematically depicts a side view of an example IC attached to a package configuration similar to that of FIG. 7 with the exception that the substrate includes a passage for allowing a cooling fluid to pass through the substrate.

FIG. 9 schematically depicts a side view of two example ICs and a package with routing element and which further includes an added packaging element that takes the form of a heat sink that is located above one of the ICs and which includes a passage through which a cooling liquid may flow.

FIG. 10 schematically depicts a side view of routing elements formed via electrochemical fabrication where a substrate on which the layers were formed has been removed and an IC attached.

### DETAILED DESCRIPTION OF PREFERRED EMBODIMENTS OF THE INVENTION

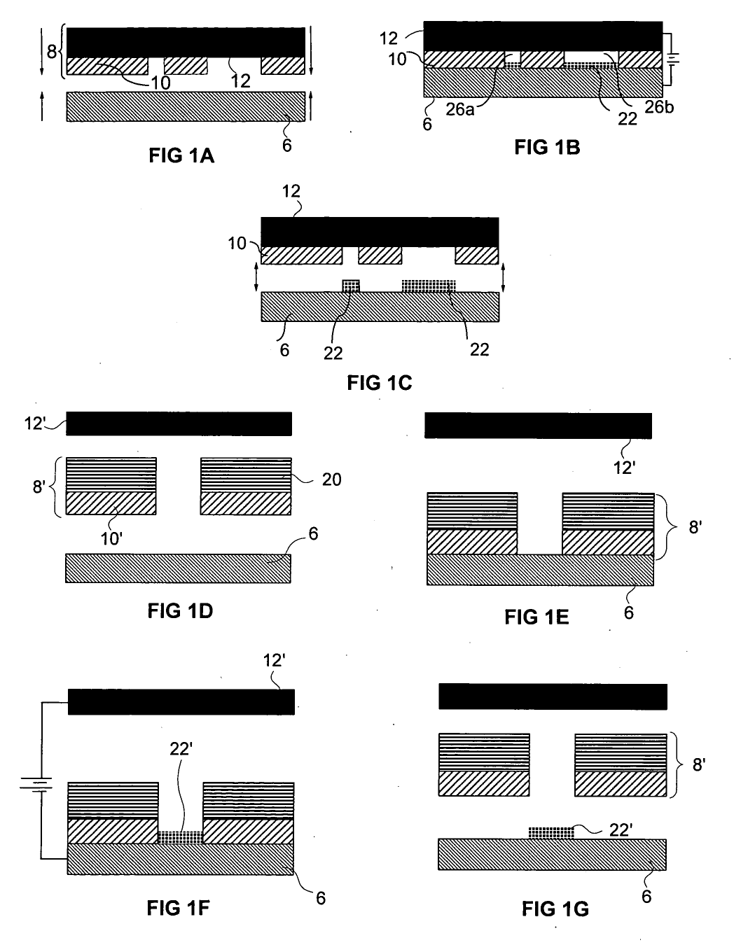

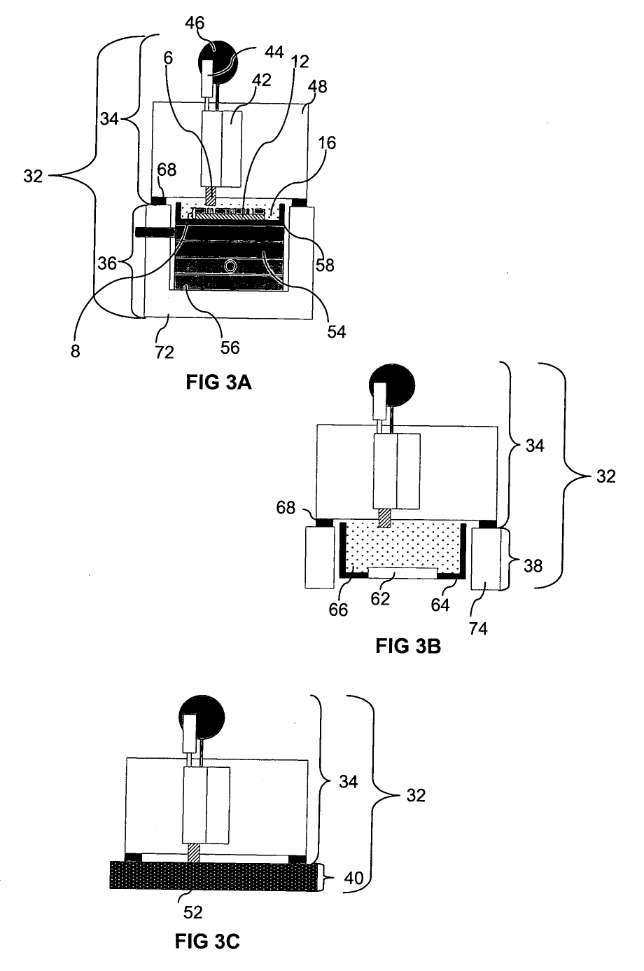

FIGS. 1A-1G, 2A-2F, and 3A-3C illustrate various features of one form of electrochemical fabrication that are known. Other electrochemical fabrication techniques are set forth in the '630 patent referenced above, in the various previously incorporated publications, in various other patents and patent applications incorporated herein by reference, still others may be derived from combinations of various approaches described in these publications, patents, and applications, or are otherwise known or ascertainable by those of skill in the art from the teachings set forth herein. All of these techniques may be combined with those of the various embodiments of various aspects of the invention to yield enhanced embodiments. Still other embodiments may be derived from combinations of the various embodiments explicitly set forth herein.

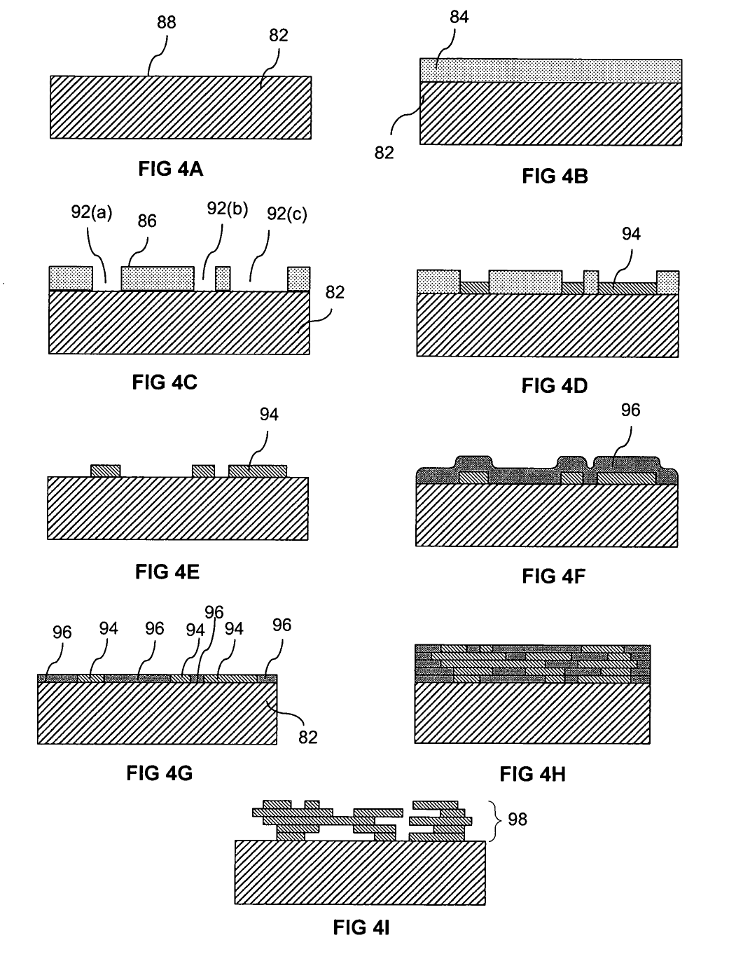

FIGS. 4A-4I illustrate various stages in the formation of a single layer of a multi-layer fabrication process where a second metal is deposited on a first metal as well as in openings in the first metal where its deposition forms part of the layer. In FIG. 4A, a side view of a substrate 82 is shown, onto which patternable photoresist 84 is cast as shown in FIG. 4B. In FIG. 4C, a pattern of resist is shown that results from the curing, exposing, and developing of the resist. The patterning of the photoresist 84 results in openings or apertures 92(a)-92(c) extending from a surface 86 of the photoresist through the thickness of the photoresist to surface 88 of the substrate 82. In FIG. 4D, a metal 94 (e.g. nickel) is shown as having been electroplated into the openings 92(a)-92(c). In FIG. 4E, the photoresist has been removed (i.e. chemically stripped) from the substrate to expose regions of the substrate 82 which are not covered with the first metal 94. In FIG. 4F, a second metal 96 (e.g., silver) is shown as having been blanket electroplated over the entire exposed portions of the substrate 82 (which is conductive) and over the first metal 94 (which is also conductive). FIG. 4G depicts the completed first layer of the structure which has resulted from the planarization of the first and second metals down to a height that exposes the first metal and sets a thickness for the first layer. In FIG. 4H the result of repeating the process steps shown in FIGS. 4B-4G several times to form a multi-layer structure are shown where each layer consists of two materials. For most applications, one of these materials is removed as shown in FIG. 4I to yield a desired 3-D structure 98 (e.g. component or device).

The various embodiments, alternatives, and techniques disclosed herein may form multi-layer structures using a single patterning technique on all layers or using different patterning techniques on different layers. For example, different types of patterning masks and masking techniques may be used or even techniques that perform direct selective depositions without the need for masking. For example, conformable contact masks may be used on some layers while nonconformable contact masks and masking operations may be used on other layers. Proximity masks and masking operations (i.e. operations that use masks that at least partially selectively shield a substrate by their proximity to the substrate even if contact is not made) may be used, and adhered masks and masking operations (masks and operations that use masks that are adhered to a substrate onto which selective deposition or etching is to occur as opposed to only being contacted to it) may be used.

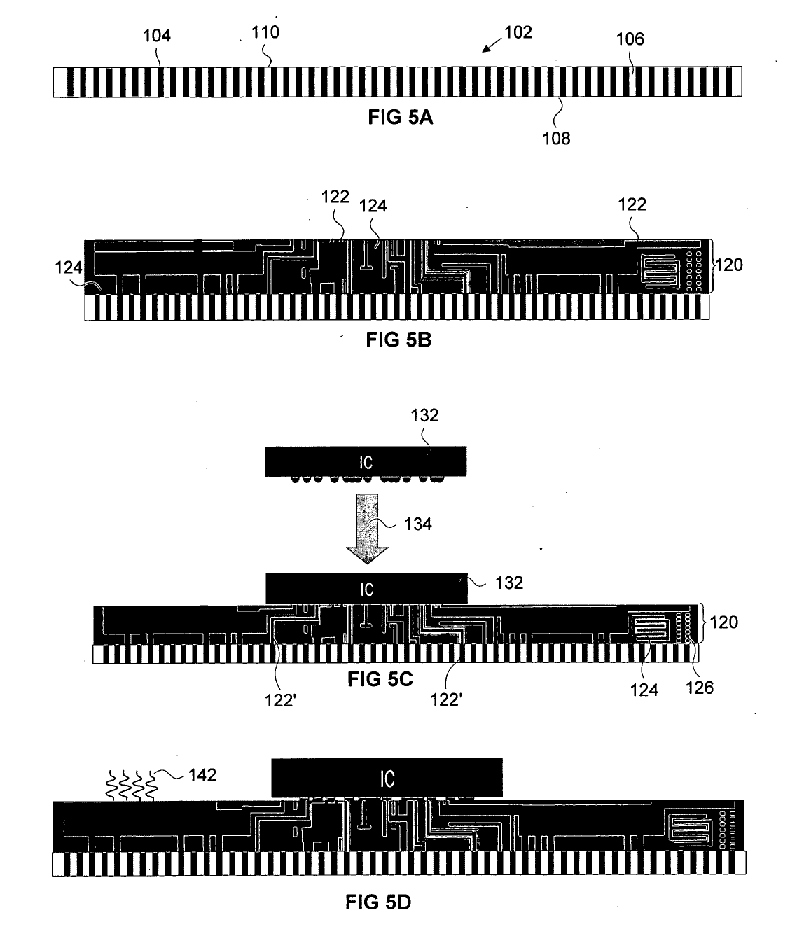

FIGS. 5A-5D schematically depict side views of various stages in a process for attaching an example IC to an example package where interconnects from the IC to at least one other component include vias that extend through a substrate on which electrochemically fabricated routing elements are formed.

FIG. 5A depicts a substrate 102 for use with some embodiments of the invention. The substrate includes a plurality of conductive vias 104 through a dielectric material 106 (e.g. a ceramic, glass, or plastic material) that extend from a lower surface 108 to an upper surface 110 of the substrate. In some embodiments the vias may be uniformly spaced with a desired pattern while in other embodiments they may be spaced in an irregular pattern. In some embodiments the via may extend along straight paths perpendicular to the top and bottom surfaces while in other embodiments, the paths may form more complex patterns including merging and/or diverging configurations and/or they may not extend perpendicular to the surfaces. In some embodiments, one or both the top and bottom surfaces may not be planar and/or the surfaces may not be parallel to one another. The substrate 102 may be formed in a variety of ways such as by low temperature co-fired ceramic (LTCC) formation methods, multi-layer ceramic (MLC) formation methods, electrochemical fabrication methods, drilling vias in a dielectric material and filling the vias with conductive material, and the like.

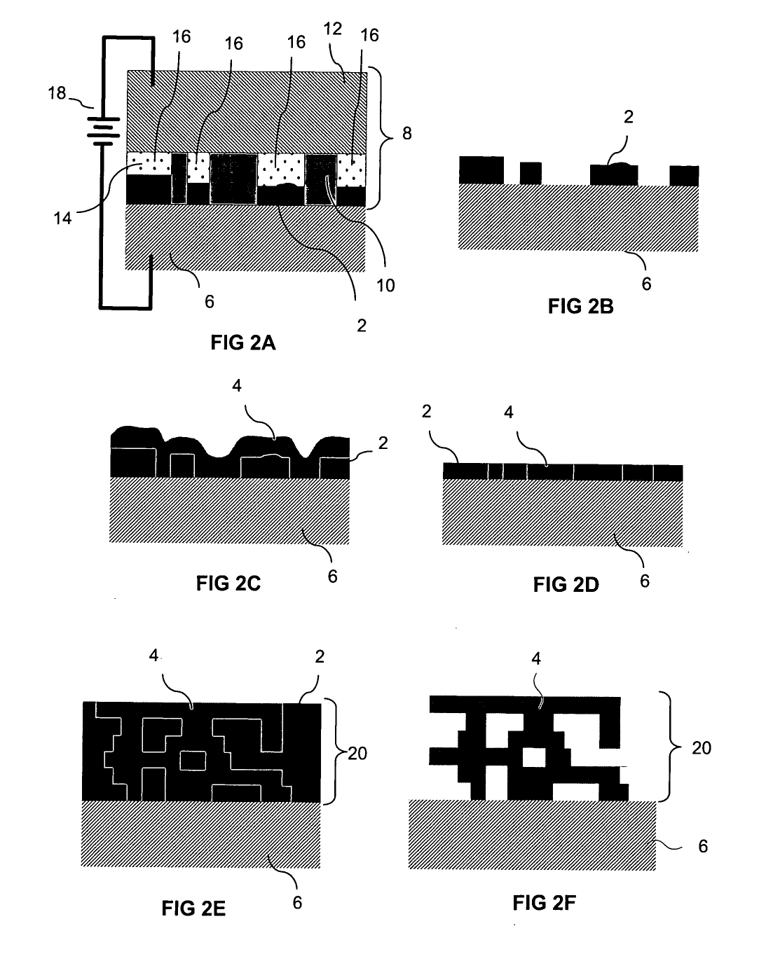

FIG. 5B depicts the state of the process after formation of a routing elements 122 has occurred via an electrochemical fabrication process. In some embodiments (as shown), the routing elements 122 may be partially encapsulated by a dielectric material 124. The electrochemical fabrication process, for example, may be one of those shown and described in association with FIGS. 2A-2F or 4A-4F or as described in the various other patent applications incorporated herein by reference. In particular, in some embodiments, the electrochemical fabrication process may involve the deposition of a conductive material and a dielectric material during the formation of each layer (e.g. as described in U.S. Patent Application No. 60/574,733, which was filed on May 26, 2004, by Lockard et al., and entitled “Methods for Electrochemically Fabricating Structures Using Adhered Masks, Incorporating Dielectric Sheets, and/or Seed layers That Are Partially Removed Via Planarization”, which is incorporated herein by reference as if set forth in full). In other embodiments, each layer may be formed with a structural material (e.g. a material used in forming routing elements) and a sacrificial material (e.g. a material occupying regions that are to contain a dielectric) where after partial or complete formation of the substrate thickness, the sacrificial material may be transformed into a desired dielectric material or removed and replaced with a desired dielectric material, after which an optional planarization operation may be used to set or reset the thickness of the structure. As shown in FIG. 5B the electrochemically fabricated structure may include various electronic components such as inductor 126 and capacitor 124. In other embodiments, other passive or active devices may be included in the structure while in still other embodiments such electronic devices need not be formed as part of, or otherwise included in, the structure. In some embodiments, added components may not be embedded in dielectric material but may instead be located within voids in the dielectric material.

FIG. 5C shows the state of the process after an IC 132 is moved along arrow 134 and brought into contact with the electrochemically fabricated structure 120, after which it may they may be bonded or otherwise connected to one another (e.g. via flip-chip attachment). Such bonding may occur, for example, using solder bumps 136 which are located on the bottom of IC 132. In other embodiments, solder bumps may be additionally or alternatively located on selected portions of the structure 120. In still other embodiments it may be possible to use other bonding or mounting techniques, such as for example, spring contactors, in combination with retention elements such as sockets, clips, hooks, adhesive, or the like.

FIG. 5D shows the state of the process after additional components, such as spring elements 142, have been added to the assembly. As can be seen in FIGS. 5C and 5D, various pads on the IC makes electric contact with elements 122 some of which electrically connect various portions pads of the IC to one another while others connect electric pads of the IC to the vias which in turn may electrically connect to other circuit elements (not shown). As can be seen in FIGS. 5B-5D, some routing elements may be in the form of simple conductive leads 122′ while others may be in the form of shielded 122″ conductive leads (e.g. coaxial elements), while still others may be in the form of waveguides (not shown), or the like. The routing elements may change dimensions, orientation, and the like for making desired electrical connections, avoiding inappropriate contact with other routing elements, enhancing electrical, thermal, and/or attributes of the package. For example, ground (GND) and voltage (VDD) connections may be made with arbitrarily wide for better current supply and lower inductance. Conductive traces in structure 120 may touch hot spots on an IC or other components to spread and/or conduct heat away.

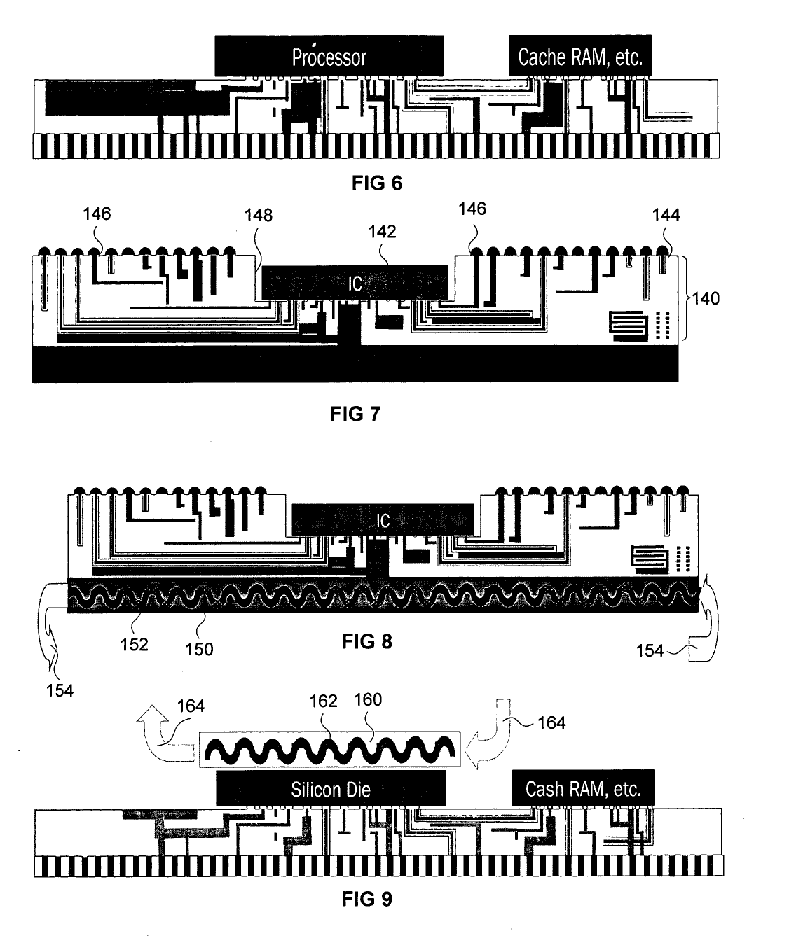

FIG. 6 schematically depicts a side view of two example ICs attached to and at least partially electrically interconnected to one another via an example package where at least a portion of the interconnects extend through routing elements formed via electrochemical fabrication. As shown, some routing elements conduct signals from each IC to the vias in the substrate, and/or from one IC to the other IC. The conducted signals may be shielded (e.g. via coaxial routing elements) or non-shielded, they may be power or ground signals, data signals, clock signals, or the like. As indicated a shielded, e.g. coaxial connection, ultra-high bandwidth connection) may be used between a processor IC (the left IC) and its memory IC (the right IC). Such shielded interconnect elements may provide: (1) non-dispersive signal transmission, (2) little or no cross-talk, (3) low loss (<0.5 dB/cm), (4) vastly improved routing flexibility for shortest point-to-point connections, (5) arbitrary thickness and low-inductance GND & VDD connections, and/or (6) routing of the main clock tree connections off the die for die size savings and power savings.

FIG. 7 schematically depicts a side view of an example IC attached to an alternative example package configuration, where the package configuration includes a conductive substrate, routing elements that provide interconnect paths from a surface of the package to the IC, and which includes passive components such as inductors and capacitors. The routing elements of the electrochemically fabricated structure 140 do not feed signals from the IC 142 to vias that extend through the substrate but instead to pads 146 located on upper surface 144 of structure 144. The pads 146 are covered with solder bumps (in this example) which may be used in establishing electrical and possibly mechanical bonding to another circuit element (not shown). In other embodiments, electrical connection may be established via other elements (e.g. wire bonding) and/or mechanical attachment may be established via other elements (e.g. adhesives, clips, sockets, or the like). The substrate in FIG. 7 is made of a solid block of conductive material which may be useful in helping conduct heat away from IC 142. In some alternative embodiments some insulated vias may pass through the substrate. In the embodiment of FIG. 7, the IC 142 is located within an indentation in the electrochemically fabricated structure so that appropriate positioning of the upper surface 144 relative to the IC 142 was obtained. In other embodiments, the IC may have an upper surface (after attachment) this is not below surface 144 but is coincident with it or which is above it.

The opening in the structure 140 into which IC 142 is placed may be formed in a variety of ways, for example, via an electrochemical fabrication process by forming routing elements from a conductive structural material, the opening 148 from a sacrificial material that is eventually removed, and the other regions from a desired dielectric material. Methods allowing such three material formation processes are set forth in a plurality of the patent applications incorporated herein by reference, for example in U.S. patent application Ser. No. 10/434,519. In other embodiments, more than one opening may exist into which a plurality of ICs or other components may be located.

In some alternatives to the embodiment of FIGS. 5A- 5D, 6, and 7, the electrochemically fabricated structure may be substantially formed from conductive material which is located in different regions by relative thin or narrow locations of dielectric material such that the dielectric material provides appropriate isolation and impedance characteristics but such that the structure as a whole as improved thermal conductive properties for remove heat from an IC or other electronic component that is mounted on it.

FIG. 8 schematically depicts a side view of an example IC attached to a package whose configuration is similar to that of FIG. 7 with the exception that the substrate 150 includes a passage 152 for allowing a cooling fluid to pass through the substrate as indicated by arrows 154.

FIG. 9 schematically depicts a side view of two example ICs and a package with routing element and which further includes an added packaging element that takes the form of a heat sink 160 that is located above one of the ICs and which includes a passage 162 through which a cooling liquid may flow as indicated by arrows 164.

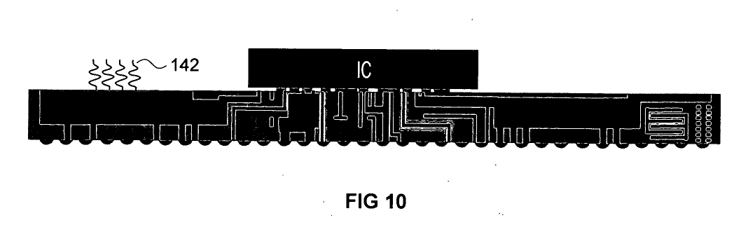

In some alternative embodiments substrates shown in FIGS. 5A-5D, FIG. 6, FIG. 7, and FIG. 9 may be removed after formation of the patterned layers, as shown in FIG. 10. As shown in FIG. 10 solder bumps may be placed on the bottom surface of the routing structure that may be used in making electrical contacts.

The packaging embodiments provided explicitly herein may be combined with the packaging embodiments provided in U.S. patent application Ser. No. 10/434,103, filed on May 7, 2003, to provide hermetically sealed packages. Such packages can protect ICs and other circuit elements from environmental damage.

In some embodiments, the packaging may include separately or integrally formed mechanically active devices (e.g. accelerometers, photonics alignment structures, pressure sensors, other sensors, actuators, and the like

Some embodiments may employ mask based selective etching operations in conjunction with blanket deposition operations. Some embodiments may form structures on a layer-by-layer basis but deviate from a strict planar layer on planar layer build up process in favor of a process that interlacing material between the layers. Such alternating build processes are disclosed in U.S. application Ser. No. 10/434,519, filed on May 7, 2003, entitled Methods of and Apparatus for Electrochemically Fabricating Structures Via Interlaced Layers or Via Selective Etching and Filling of Voids which is herein incorporated by reference as if set forth in full.

Some embodiments may employ diffusion bonding or the like to enhance adhesion between successive layers of material. Various teachings concerning the use of diffusion bonding in electrochemical fabrication processes are set forth in U.S. patent application Ser. No. 10//841,384 which was filed May 7, 2004 by Cohen et al. which is entitled “Method of Electrochemically Fabricating Multilayer Structures Having Improved Interlayer Adhesion” and which is hereby incorporated herein by reference as if set forth in full. This application is hereby incorporated herein by reference as if set forth in full.

In some embodiments, integrated circuits may be packaged using compliant contact elements (e.g. microprobes) and as such, enhanced embodiments of the present invention may result from the combination of microprobe fabrication technology with the teachings expressly set forth herein. Teaching about microprobes and electrochemical fabrication techniques are set forth in a number of U.S. patent applications which were filed on Dec. 31, 2003. These Filings include: (1) U.S. Patent Application No. 60/533,933, by Arat et al. and which is entitled “Electrochemically Fabricated Microprobes”; (2) U.S. Patent Application No. 60/533,975, by Kim et al. and which is entitled “Microprobe Tips and Methods for Making”; (3) U.S. Patent Application No. 60/533,947, by Kumar et al. and which is entitled “Probe Arrays and Method for Making”; and (4) U.S. Patent Application No. 60/533,948, by Cohen et al. and which is entitled “Electrochemical Fabrication Method for Co-Fabricating Probes and Space Transformers”. These patent filings are each hereby incorporated herein by reference as if set forth in full herein.

The techniques disclosed explicitly herein may benefit by combining them with the techniques disclosed in U.S. patent application Ser. No. ______ filed concurrently herewith by Chen et al. and entitled “Pin-Type Probes for Contacting Electronic Circuits and Methods for Making Such Probes” (Corresponding to Microfabrica Docket No. P-US139-A-MF); U.S. patent application Ser. No. ______ filed concurrently herewith by Chen et al. and entitled “Vertical Microprobes for Contacting Electronic Components and Method for Making Such Probes” (corresponding to Microfabrica Docket No. P-US129-A-MF); U.S. patent application Ser. No. ______ filed concurrently herewith by Kim et al. and entitled “Microprobe Tips and Methods For Making” (corresponding to Microfabrica Docket No. P-US122-A-MF); U.S. patent application Ser. No. ______ filed concurrently herewith by Kumar et al. and entitled “Probe Arrays and Methods for Making” (corresponding to Microfabrica Docket No. P-US123-A-MF); and U.S. patent application Ser. No. ______ filed concurrently herewith by Cohen et al. and entitled “Electrochemical Fabrication Process for Forming Multilayer Multimaterial Microprobe Structures” (corresponding to Microfabrica Docket No. P-US138-A-MF).

Further teachings about planarizing layers and setting layers thicknesses and the like are set forth in the following U.S. patent applications which were filed Dec. 31, 2003: (1) U.S. patent application Ser. No. 60/534,159 by Cohen et al. and which is entitled “Electrochemical Fabrication Methods for Producing Multilayer Structures Including the use of Diamond Machining in the Planarization of Deposits of Material” and (2) U.S. patent application Ser. No. 60/534,183 by Cohen et al. and which is entitled “Method and Apparatus for Maintaining Parallelism of Layers and/or Achieving Desired Thicknesses of Layers During the Electrochemical Fabrication of Structures”. The techniques disclosed explicitly herein may benefit by combining them with the techniques disclosed in U.S. patent application Ser. No. ______ filed concurrently herewith by Frodis et al. and entitled “Method and Apparatus for Maintaining Parallelism of Layers and/or Achieving Desired Thicknesses of Layers During the Electrochemical Fabrication of Structures” (corresponding to Microfabrica Docket No. P-US132-A-MF). These patent filings are each hereby incorporated herein by reference as if set forth in full herein.

Additional teachings concerning the formation of structures on dielectric substrates and/or the formation of structures that incorporate dielectric materials into the formation process and possibility into the final structures as formed are set forth in a number of patent applications: (1) U.S. Patent Application No. 60/534,184, by Cohen, which as filed on Dec. 31, 2003, and which is entitled “Electrochemical Fabrication Methods Incorporating Dielectric Materials and/or Using Dielectric Substrates”; (2) U.S. Patent Application No. 60/533,932, by Cohen, which was filed on Dec. 31, 2003, and which is entitled “Electrochemical Fabrication Methods Using Dielectric Substrates”; (3) U.S. Patent Application No. 60/534,157, by Lockard et al., which was filed on Dec. 31, 2004, and which is entitled “Electrochemical Fabrication Methods Incorporating Dielectric Materials”; (4) U.S. patent application Ser. Nos. 10/841,300 and 60/574,733, both by Lockard et al., filed on May 7, 2004 and May 26, 2004, respectively, and both entitled “Methods for Electrochemically Fabricating Structures Using Adhered Masks, Incorporating Dielectric Sheets, and/or Seed Layers that are Partially Removed Via Planarization”; and U.S. Patent Application No. 60/533,895, by Lembrikov et al., which was filed on Dec. 31, 2003, and which is entitled “Electrochemical Fabrication Method for Producing Multi-layer Three-Dimensional Structures on a Porous Dielectric”. The techniques disclosed explicitly herein may benefit by combining them with the techniques disclosed in U.S. patent application Ser. No. ______ filed concurrently herewith by Cohen et al. and entitled “Electrochemical Fabrication Methods Incorporating Dielectric Materials and/or Using Dielectric Substrates” (corresponding to Microfabrica Docket No. P-US128-A-MF) and U.S. patent application Ser. No. ______ filed concurrently herewith by Dennis R. Smalley and entitled “Method of Forming Electrically Isolated Structures Using Thin Dielectric Coatings” (corresponding to Microfabrica Docket No. P-US121-A-MF). These patent filings are each hereby incorporated herein by reference as if set forth in full herein.

Many other alternative embodiments will be apparent to those of skill in the art upon reviewing the teachings herein. Further embodiments may be formed from a combination of the various teachings explicitly set forth in the body of this application. Even further embodiments may be formed by combining the teachings set forth explicitly herein with teachings set forth in the following patents and patent applications each of which is hereby incorporated herein by reference:

Various other embodiments of the present invention exist. Some embodiments may not use any blanket deposition process and/or they may not use a planarization process. Some embodiments may involve the selective deposition of a plurality of different materials on a single layer or on different layers. Some embodiments may use selective deposition processes or blanket deposition processes on some or all layers that are not electrodeposition processes. Some embodiments may, for example, use nickel, copper, gold, and/or dielectric materials as structural materials while other embodiments may use different materials. Some embodiments may remove a sacrificial material while other embodiments may not. Some embodiments may employ mask based selective etching operations in conjunction with blanket deposition operations. Some embodiments may form structures on a layer-by-layer basis but which deviate from a strict planar layer on planar layer build up process in favor of a process that interlaces material between the layers. Such alternating build processes are disclosed in U.S. application Ser. No. 10/434,519, filed on May 7, 2003, entitled Methods of and Apparatus for Electrochemically Fabricating Structures Via Interlaced Layers or Via Selective Etching and Filling of Voids which is herein incorporated by reference as if set forth in full.

Many other alternative embodiments will be apparent to those of skill in the art upon reviewing the teachings herein. Further embodiments may be formed from a combination of the various teachings explicitly set forth in the body of this application. Even further embodiments may be formed by combining the teachings set forth explicitly herein with teachings set forth in the various applications and patents referenced herein, each of which is incorporated herein by reference.

In view of the teachings herein, many further embodiments, alternatives in design and uses of the instant invention will be apparent to those of skill in the art. As such, it is not intended that the invention be limited to the particular illustrative embodiments, alternatives, and uses described above but instead that it be solely limited by the claims presented hereafter.

1. A fabrication process for fabricating a package for holding an electronic component, comprising:
(a) forming and adhering a layer of material to a previously formed layer and/or to a substrate, wherein the layer comprises a desired pattern of at least one material; and
(b) repeating the forming and adhering operation of (a) a plurality of times to build up a configuration of conductive interconnect elements in a configuration of a desired package, wherein the plurality of layers are adhered to one another and comprise at least one of (i) at least one structural material and at least one sacrificial material or (ii) at least two structural materials one of which is a conductor and one of which is a dielectric.

2. The process of claim 1 wherein the package comprises metal electrodeposited or electroless deposited on a layer by layer basis where the height of at least some layers is set by a planarization operation that planarizes an interconnect material and at least one other material.

3. The process of claim 1 wherein the package comprises vias and traces that coexist on at least some layers.

4. The process of claim 1 wherein the package comprises at least one more coaxial interconnects.

5. The process of claim 1 wherein the package comprises interconnects having traces having at least two different widths.

6. The process of claim 1 wherein the package comprises interconnects comprising vias that have at least two different widths.

7. The process of claim 1 wherein the package comprises interconnects have trace thicknesses that are at least as thick as some planarized thicknesses of a dielectric material.

8. The process of claim 1 wherein the package comprises interconnects having trace thicknesses that are at least as thick as the differential height between some interconnect traces.

9. The process of claim 1 wherein the at least one layer of the package is formed using a process comprising: patterning a first material, applying a non-planar seed layer, electrodepositing a second material, and trimming off at least a portion of the deposited first material.

10. A fabrication process for fabricating a packaged electronic component, comprising:
providing a substrate having conductive vias;
forming routing elements on the substrate which have first and second ends, where at least some of the first ends are connectable to a first electronic component and at least some of the second ends connect to vias on the substrate; and
attaching the first electronic component to at least some of the first ends.

11. A fabrication process for fabricating a packaged electronic component, comprising:
providing a substrate;
forming routing elements on the substrate which have first and second ends, where at least some of the first ends are connectable to a first electronic component and at least some of the second ends are connectable to a second electronic component; and
attaching the first and second electronic components to the at least some of the first ends and second ends, respectively.
